(19) United States
(12) Patent Application Publication
(10) Pub. No.: US 2025/0393217 A1
(43) Pub. Date: Dec. 25, 2025

(54) SEMICONDUCTOR MEMORY DEVICE AND ELECTRONIC SYSTEM INCLUDING THE SAME

(71) Applicant: SAMSUNG ELECTRONICS CO., LTD., SUWON-SI (KR)

(72) Inventor: Ki Joon KIM, Suwon-si (KR)

(21) Appl. No.: 18/990,396

(22) Filed: Dec. 20, 2024

(30) Foreign Application Priority Data
Jun. 19, 2024 (KR) 10-2024-0079611

(51) Int. Cl. H10B 51/30; H10B 51/10; H10B 51/20; H10B 53/40

(52) U.S. Cl. CPC H10B 51/30; H10B 51/10; H10B 51/20; H10B 53/40

(57) ABSTRACT

A semiconductor memory device includes a substrate, a mold structure disposed on the substrate, and a channel structure penetrating through the mold structure and extending in a first direction. The mold structure includes a plurality of mold insulating layers and a plurality of gate electrodes alternatively stacked in a first direction. The channel structure includes, a semiconductor pattern, a dielectric layer, and a ferroelectric layer, each disposed between the plurality of gate electrodes and the semiconductor pattern. A concentration of a specific element in the dielectric layer is greater than a concentration of the specific element in the ferroelectric layer. The specific element includes carbon and/or nitrogen.

### CROSS-REFERENCE TO RELATED APPLICATION

This application claims priority under 35 U.S.C. § 119 to Korean Patent Application No. 10-2024-0079611, filed in the Korean Intellectual Property Office on Jun. 19, 2024, the entire contents of which are hereby incorporated by reference.

### TECHNICAL FIELD

The present disclosure relates to semiconductors and, more specifically, to a semiconductor memory device and an electronic system including the same.

### DISCUSSION OF THE RELATED ART

There is a growing demand for semiconductor memory devices that can store large amounts of data, particularly in an electronic systems with significant storage requirements. To address this need, researchers are exploring methods to increase the data storage capacity of these devices. One such approach involves transitioning from a two-dimensional arrangement of memory cells to a three-dimensional configuration which allows for higher storage density within the same physical footprint.

### SUMMARY

A semiconductor memory device includes a substrate, a mold structure disposed on the substrate, and a channel structure penetrating through the mold structure and extending in a first direction. The mold structure includes a plurality of mold insulating layers and a plurality of gate electrodes alternatively stacked in a first direction. The channel structure includes a semiconductor pattern, a dielectric layer, and a ferroelectric layer. The dielectric layer and the ferroelectric layer are each disposed between the plurality of gate electrodes and the semiconductor pattern. A concentration of a specific element in the dielectric layer is greater than a concentration of the specific element in the ferroelectric layer. The specific element includes carbon and/or nitrogen.

A semiconductor memory device includes a peripheral circuit structure, and a cell structure stacked on the peripheral circuit structure. The cell structure includes a substrate, a mold structure disposed on the substrate, and a channel structure penetrating through the mold structure and extending in a first direction. The mold structure includes a plurality of mold insulating layers and a plurality of gate electrodes alternately stacked on each other in the first direction. The channel structure includes a semiconductor pattern, a dielectric layer, and a ferroelectric layer disposed between the plurality of gate electrodes and the semiconductor pattern. A concentration of a specific element in the dielectric layer is greater than a concentration of the specific element in the ferroelectric layer. The specific element includes carbon and/or nitrogen.

An electronic system includes a main substrate, a semiconductor memory device disposed on the main substrate, the semiconductor memory device including a peripheral circuit structure, and a cell structure stacked on the peripheral circuit structure. A controller is disposed on the main substrate, the controller being electrically connected to the semiconductor memory device. The cell structure includes a substrate, a mold structure disposed on the substrate, and a channel structure penetrating through the mold structure and extending in a first direction. The mold structure includes a plurality of mold insulating layers and a plurality of gate electrodes alternately stacked in the first direction. The channel structure includes a semiconductor pattern, a dielectric layer, and a ferroelectric layer. The dielectric pattern and the ferroelectric layer are each disposed between the plurality of gate electrodes and the semiconductor pattern. A concentration of a specific element in the dielectric layer is greater than a concentration of the specific element in the ferroelectric layer. The specific element includes carbon and/or nitrogen.

### BRIEF DESCRIPTION OF THE DRAWINGS

The above and other embodiments and features of the present disclosure will become more apparent by describing in detail example embodiments thereof with reference to the attached drawings, in which:

FIG. 1 is a plan view illustrating a semiconductor memory device according to embodiments;

FIG. 2 is a cross-sectional view taken along line A-A of FIG. 1;

FIG. 3 is an enlarged view illustrating the region Q1 of FIG. 2;

FIG. 4 is a graphical representation schematically illustrating a carbon concentration along the ASL line of FIG. 3;

FIG. 5 is a diagram illustrating a semiconductor memory device according to embodiments;

FIG. 6 is a diagram illustrating a semiconductor memory device according to embodiments;

FIG. 7 is a diagram illustrating a semiconductor memory device according to embodiments;

FIG. 8 is a diagram illustrating a semiconductor memory device according to embodiments;

FIG. 9 is a diagram illustrating a semiconductor memory device according to embodiments;

FIG. 10 is a diagram illustrating a semiconductor memory device according to embodiments;

FIG. 11 is a diagram illustrating a semiconductor memory device according to embodiments;

FIG. 12 is a diagram illustrating a semiconductor memory device according to embodiments;

FIG. 13 is a block diagram exemplarily illustrating an electronic system according to embodiments;

FIG. 14 is an example perspective view illustrating an electronic system including a semiconductor memory device according to embodiments; and

FIG. 15 is a schematic cross-sectional view taken along line V-V of FIG. 14.

### DETAILED DESCRIPTION

Hereinafter, a semiconductor memory device and a method for manufacturing the same according to embodiments of the present disclosure will be described in detail with reference to the drawings.

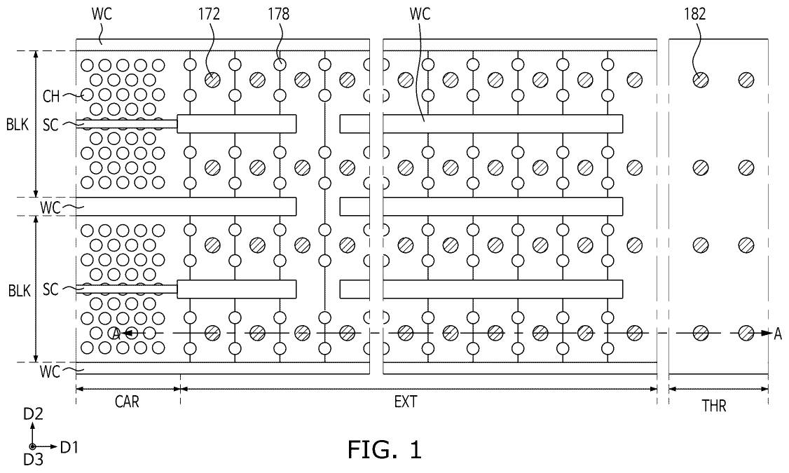

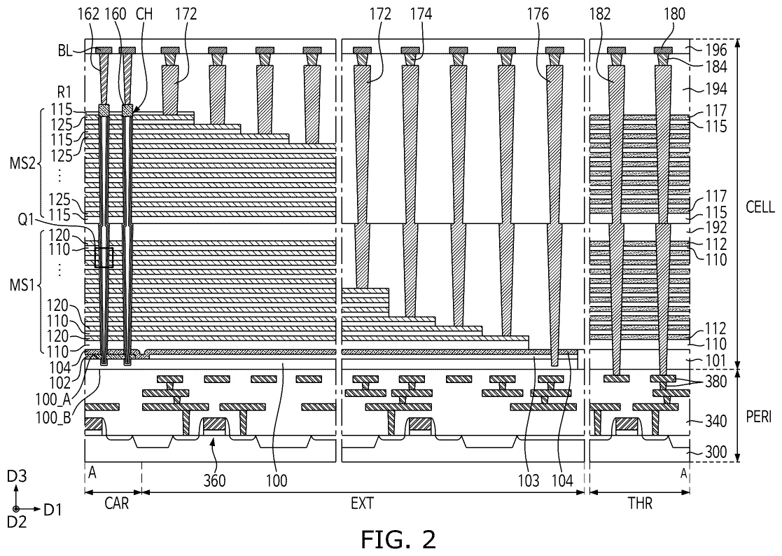

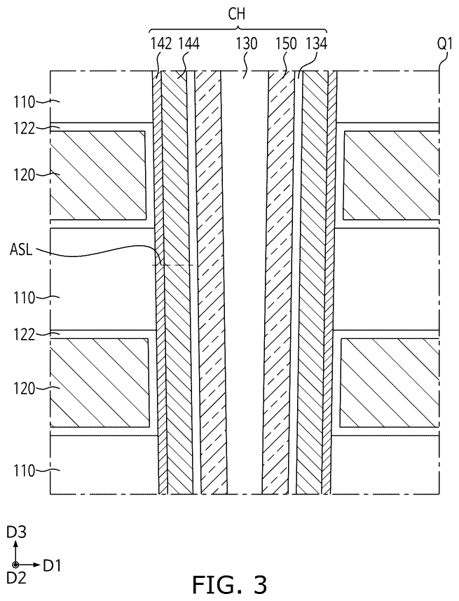

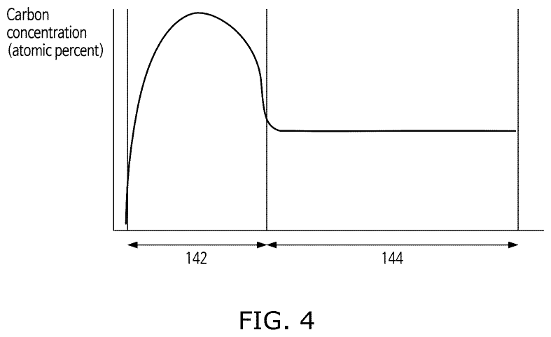

FIG. 1 is a plan view illustrating a semiconductor memory device according to embodiments. FIG. 2 is a cross-sectional view taken along line A-A of FIG. 1. FIG. 3 is an enlarged view illustrating the region Q1 of FIG. 2. FIG. 4 is a graphical representation schematically illustrating a carbon concentration along the ASL line of FIG. 3.

Referring to FIGS. 1 to 4, a semiconductor memory device 1100, according to embodiments, may include a cell structure CELL and a peripheral circuit structure PERI.

The cell structure CELL may include a cell substrate 100, a first mold structure MS1, a second mold structure MS2, a channel structure CH, a channel pad 160, a bit line BL, a word line contact 172, a source contact 176, a through via 182, a first wiring structure 180, etc.

The cell substrate 100 may include a cell array region CAR, an extended region EXT, and a through region THR.

A memory cell array including a plurality of memory cells may be formed on the cell array region CAR. The channel structure CH, the first mold structure MS1, the second mold structure MS2, the bit line BL, etc. may be disposed on the cell array region CAR.

The extended region EXT may be disposed proximate to the cell array region CAR. For example, the extended region EXT may surround the cell array region CAR on at least two sides thereof. The word line contact 172, a support structure 178, etc. may be disposed on the extended region EXT.

The through region THR may be disposed outside of the extended region EXT. For example, the through region THR may be disposed on one side of the extended region EXT, but embodiments are not necessarily limited thereto. The through via 182 may be disposed in the through region THR.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In embodiments, the cell substrate 100 may include polysilicon (poly Si).

The cell substrate 100 may include a first surface 100_A and a second surface 100_B opposite to the first surface 100_A. The first surface 100_A of the cell substrate 100 may be a surface on which the first mold structure MS1 and the channel structure CH are disposed. The first surface 100_A of the cell substrate 100 may be referred to as a front side of the cell substrate 100. The second surface 100_B of the cell substrate 100 may be referred to as a back side of the cell substrate 100.

The first mold structure MS1 may be formed on the first surface 100_A of the cell substrate 100. The first mold structure MS1 may include a plurality of first mold insulating layers 110 and a plurality of first gate electrodes 120 alternately stacked on each other in a third direction D3. Each of the first mold insulating layer 110 and each of the first gate electrodes 120 may have a layered structure extending parallel to the first surface 100_A of the cell substrate 100. The first gate electrodes 120 may be spaced apart from each other by the first mold insulating layer 110 and may be sequentially stacked on each other on the cell substrate 100.

As used herein, the phrase, “extending in a direction” when applied to a two or three-dimensional shape pertains to the direction in which the longest dimension of the shape extends.

The second mold structure MS2 may be formed on the first mold structure MS1. The second mold structure MS2 may include a plurality of second mold insulating layers 115 and a plurality of second gate electrodes 125 which are alternately stacked on each other. Each of the second mold insulating layer 115 and each of the second gate electrodes 125 may have a layered structure extending parallel to the first surface 100_A of the cell substrate 100. The second gate electrodes 125 may be spaced apart from each other by the second mold insulating layer 115 and may be sequentially stacked on each other on the first mold structure MS1.

In embodiments, some of the plurality of first gate electrodes 120 may be used as a ground selection line GSL and an erase control line ECL of the semiconductor memory device 1100. For example, the first gate electrodes 120, of the plurality of first gate electrodes 120, that are adjacent to a source structure 102 and 104 may be used as the erase control line ECL. The erase control line ECL may be used as a gate electrode of an erase transistor. The erase transistor may generate a gate induced drain leakage current (GIDL) to perform an erase operation on a plurality of memory cell transistors. The first gate electrodes 120 adjacent to the erase control line ECL may be provided as the ground selection line GSL. However, embodiments are not necessarily limited thereto. The arrangement and number of the ground selection lines GSL may vary.

In embodiments, some of the plurality of second gate electrodes 125 may be provided as a string selection line SSL of the semiconductor memory device 1100. For example, the second gate electrode 125, of the plurality of second gate electrodes 125, that is adjacent to the bit line BL may be provided as the string selection line SSL. However, embodiments are not necessarily limited thereto. The arrangement and number of string selection lines SL may vary.

Each of the first mold insulating layer 110 and the second mold insulating layer 115 may include an electrically insulating material. For example, each of the first mold insulating layer 110 and the second mold insulating layer 115 may include silicon oxide, silicon nitride, and/or silicon oxynitride, but embodiments are not necessarily limited thereto.

Each of the first gate electrodes 120 and the second gate electrode 125 may include an electrically conductive material. For example, each of the first gate electrodes 120 and the second gate electrode 125 may include a metal such as tungsten (W), cobalt (Co), nickel (Ni), or a semiconductor material such as silicon, but embodiments are not necessarily limited thereto.

Although FIG. 2 illustrates that the number of mold structures MS1 and MS2 is two, embodiments are not necessarily limited thereto. For example, the number of mold structures MS1 and MS2 may be three, four, or more.

The channel structure CH may penetrate through each of the first mold structure MS1 and the second mold structure MS2. For example, the channel structure CH may penetrate through and intersect each of the plurality of first mold insulating layers 110 and the plurality of first gate electrodes 120. The channel structure CH may penetrate through and intersect each of the plurality of second mold insulating layers 115 and the plurality of second gate electrodes 125. The channel structure CH may extend in the third direction D3. The channel structure CH may have a pillar shape (e.g., a cylindrical shape) extending in the third direction D3.

The channel structure CH may have a bent portion between the first mold structure MS1 and the second mold structure MS2. In embodiments, the cross section of the channel structure CH disposed in the first mold structure MS1 may have an inclined side surface such that its width is progressively narrowed toward the cell substrate 100. However, embodiments are not necessarily limited thereto.

In embodiments, the channel structures CH may be arranged in a zigzag form. For example, as illustrated in FIG. 1, the channel structures CH may cross itself in a first direction D1 and a second direction D2. The channel structures CH disposed in the zigzag form may further increase the integration density of the semiconductor memory device. In embodiments, the channel structures CH may be arranged in a honeycomb form.

The channel structure CH may include a semiconductor pattern 150, a dielectric layer 142, a ferroelectric layer 144, a first interface layer 134, and a filling insulating layer 130.

The semiconductor pattern 150 may extend in the third direction D3 and may penetrate through the first mold structure MS1 and the second mold structure MS2. The semiconductor pattern 150 is illustrated as having a cup shape, but embodiments are not necessarily limited thereto. For example, the semiconductor pattern 150 may have various shapes such as a cylindrical shape, a rectangular cylindrical shape, a filled pillar shape, etc. For example, the semiconductor pattern 150 may include a semiconductor material such as a single crystal silicon, a polycrystalline silicon, an organic semiconductor material, a carbon nanostructure, etc., but embodiments are not necessarily limited thereto.

The dielectric layer 142 and the ferroelectric layer 144 may be disposed between the plurality of first gate electrodes 120 and the semiconductor pattern 150. The ferroelectric layer 144 may be disposed on the semiconductor pattern 150. The ferroelectric layer 144 may extend along the semiconductor pattern 150 in the third direction D3. The dielectric layer 142 may be disposed on the ferroelectric layer 144. The dielectric layer 142 may extend along the ferroelectric layer 144 in the third direction D3. The dielectric layer 142 may be disposed between the plurality of first gate electrodes 120 and the ferroelectric layer 144.

The thickness of the dielectric layer 142 may be less than the thickness of the ferroelectric layer 144. The thickness may refer to a thickness in a direction perpendicular to a direction in which the dielectric layer 142 and the ferroelectric layer 144 extend. For example, if the dielectric layer 142 extends in the third direction D3, the thickness of the dielectric layer 142 may be a thickness in the first direction D1 or the second direction D2. As an example, if the dielectric layer 142 has a tapered shape with its width progressively narrowed toward the lower portion, the thickness of the dielectric layer 142 may refer to a thickness in a direction perpendicular to the length direction in which the dielectric layer 142 extends.

In embodiments, the thickness of the dielectric layer 142 may be within a range of 0.1 nm to 3 nm, inclusive. The thickness of the ferroelectric layer 144 may be 10 nm or less. However, embodiments are not necessarily limited thereto.

In embodiments, unlike the illustration, a boundary surface between the dielectric layer 142 and the ferroelectric layer 144 might not be distinguishable. For example, the dielectric layer 142 and the ferroelectric layer 144 may be integrated into a single structure.

The ferroelectric layer 144 may include a ferroelectric material. For example, the ferroelectric layer 144 may include a hafnium-based compound having ferroelectric properties. For example, the ferroelectric layer 144 may include hafnium dioxide (HfO₂), hafnium zinc oxide (HfZnO), hafnium silicate oxide (HfSiO), hafnium silicon oxynitride (HfSiON), hafnium tantalum oxide (HfTaO), hafnium titanium oxide (HfTiO), hafnium zirconium oxide (HfZrO), or a combination thereof. In addition, for example, the ferroelectric layer 144 may include a ferroelectric material having a perovskite structure such as lead zirconate titanate (PbZrₓTi₁₋ₓO₃) (PZT), barium titanate (BaTiO₃), lead titanate (PbTiO₃), etc. The ferroelectric layer 144 may include at least one dopant such as carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and/or lanthanum (La). The ferroelectric layer 144 may be formed of a crystalline material. For example, the ferroelectric layer 144 may have an orthorhombic crystal structure.

The dielectric layer 142 may include a paraelectric, a ferroelectric, and/or an anti-ferroelectric material. The dielectric layer 142 may include hafnium dioxide (HfO₂), zirconium dioxide (ZrO₂), silicon dioxide (SiO₂), silicon nitride (SiN), titanium dioxide (TiO₂), aluminum oxide (Al₂O₃), vanadium dioxide (VO₂), or a combination thereof. In an aspect, the dielectric layer 142 may include a two-dimensional material including carbon. For example, the two-dimensional material may include hexagonal boron nitride (H-BN), hydrocarbon (HC), monolayer amorphous carbon (MAC), etc. The two-dimensional material may have a layered structure.

The dielectric layer 142 and the ferroelectric layer 144 may include the same element. For example, the dielectric layer 142 and the ferroelectric layer 144 may include a specific element. The concentration of the specific element of the dielectric layer 142 may be higher than the concentration of the specific element of the ferroelectric layer 144. In embodiments, the specific element included in the dielectric layer 142 and the ferroelectric layer 144 may be carbon (C) and/or nitrogen (N).

If the specific element is carbon, the carbon concentration of the dielectric layer 142 and the carbon concentration of the ferroelectric layer 144 may be the same as illustrated in FIG. 4. Referring to FIG. 4, the carbon concentration of the dielectric layer 142 may be higher than that of the ferroelectric layer 144. Although the specific element is described as carbon, the specific element may be nitrogen and a graph of nitrogen concentration may be similar to FIG. 4. For example, the nitrogen concentration of the dielectric layer 142 may be higher than the nitrogen concentration of the ferroelectric layer 144. For example, the concentration of the specific element of the dielectric layer 142 may be 2 at % (atomic percent) to 20 at %.

The dielectric layer 142 may be provided as a seed layer for forming the ferroelectric layer 144. The dielectric layer 142 including the specific element (e.g., carbon or nitrogen) may suppress the excessive grain size of the ferroelectric layer 144. For example, if the ferroelectric layer 144 is formed on the dielectric layer 142, excessive grain growth in the ferroelectric layer 144 may be suppressed. In addition, the dispersion of the grain size of the ferroelectric layer 144 can be better controlled. Accordingly, electrical characteristics and reliability of the semiconductor memory device can be increased.

In embodiments, a barrier layer 122 may be disposed on the first gate electrodes 120. The barrier layer 122 may surround the first gate electrodes 120. The dielectric layer 142 may be in contact with the barrier layer 122. The barrier layer 122 may include an electrically conductive material.

In embodiments, the first interface layer 134 may be disposed between the ferroelectric layer 144 and the semiconductor pattern 150. The first interface layer 134 may be in contact with an outer surface of the semiconductor pattern 150. For example, the first interface layer 134 may include a silicon oxide or a high-k material (e.g., aluminum oxide (Al₂O₃), hafnium oxide (HfO₂)) having a higher dielectric constant than that of the silicon oxide.

The filling insulating layer 130 may fill the inside of the semiconductor pattern 150. For example, the filling insulating layer 130 may be interposed between the semiconductor patterns 150. For example, the filling insulating layer 130 may include an insulating material, for example, a silicon oxide, but embodiments are not necessarily limited thereto.

The channel pad 160 may be disposed below the channel structure CH. The channel pad 160 may be disposed on a bottom end of the channel structure CH and may be electrically connected to the semiconductor pattern 150. For example, the channel pad 160 may include polysilicon doped with an impurity, but is not necessarily limited thereto. However, embodiments are not necessarily limited thereto.

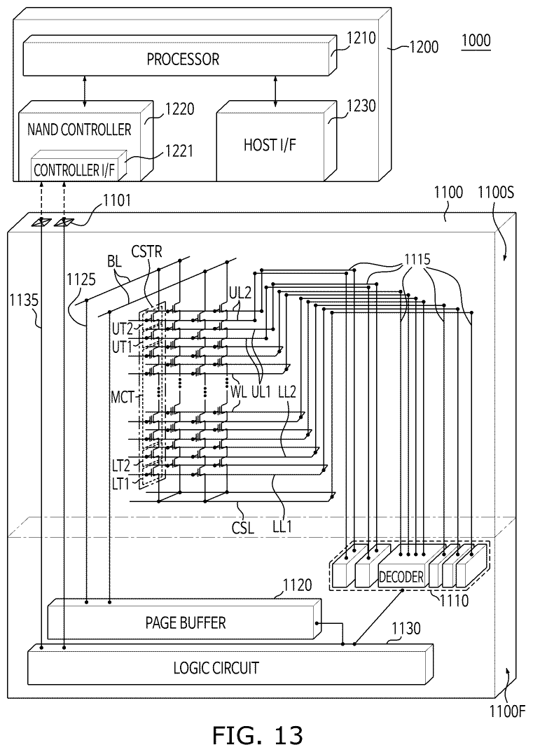

In embodiments, the source structure 102 and 104 may be formed on the cell substrate 100. For example, the source structure 102 and 104 may be disposed on the first surface 100_A of the cell substrate 100. The source structure 102 and 104 may be disposed between the cell substrate 100 and the first mold structure MS1. For example, the source structure 102 and 104 may extend along an upper surface of the cell substrate 100. The source structure 102 and 104 may be connected to the semiconductor pattern 150 and/or an information storage film 140 of the channel structure CH. The source structure 102 and 104 may be used as a common source line (e.g., CSL of FIG. 13) of the semiconductor memory device 1100. For example, the source structure 102 and 104 may include polysilicon or metal doped with an impurity, but embodiments are not necessarily limited thereto.

In embodiments, the channel structure CH may penetrate through the source structure 102 and 104. For example, a lower portion of the channel structure CH may penetrate through the source structure 102 and 104 and disposed in the cell substrate 100.

In embodiments, the source structure 102 and 104 may include multiple films. For example, the source structure 102 and 104 may include a first source layer 102 and a second source layer 104, which are sequentially stacked on each other on the cell substrate 100. Hereinafter, the source structure 102 and 104 may be referred to as a first source layer 102 and a second source layer 104. Each of the first source layer 102 and the second source layer 104 may include polysilicon doped with an impurity or polysilicon undoped with an impurity, but embodiments are not necessarily limited thereto. The first source layer 102 may be in contact with the semiconductor pattern 150 and may be provided as a common source line (e.g., CSL of FIG. 13) of the semiconductor memory device 1100. The second source layer 104 may be used as a support layer for preventing the mold stack from collapsing or falling in a replacement process for forming the first source layer 102.

A base insulating layer may be interposed between the cell substrate 100 and the source structure 102 and 104. For example, the base insulating film may include silicon oxide, silicon nitride, and/or silicon oxynitride, but is not necessarily limited thereto.

In embodiments, the source structure 102 and 104 might not be formed in the extended region EXT where an insulating substrate 101 is formed. It is illustrated that an upper surface of the insulating substrate 101 is coplanar with the upper surface of the source structure 102 and 104, but this is merely an example. As an example, the upper surface of the insulating substrate 101 may be disposed at a higher level than that of the upper surface of the source structure 102 and 104.

In embodiments, a source sacrificial film 103 may be formed on a portion of the cell substrate 100. For example, the source sacrificial film 103 may be formed on a portion of the cell substrate 100 in the extended region EXT. The source sacrificial film 103 may include a material having etch selectivity with respect to the first and second mold insulating layers 110 and 115. For example, the first and second mold insulating layers 110 and 115 may include silicon oxide, and the source sacrificial film 103 may include silicon nitride. The source sacrificial film 103 may be a layer remaining after a portion of the source structure 102 and 104 is replaced with the source sacrificial film 103 in the manufacturing process.

The block isolation pattern WC may extend in the first direction D1 to cut the first and second mold structures MS1 and MS2. At least a portion of the block isolation pattern WC may completely cut the first and second mold structures MS1 and MS2. At least a portion of the block isolation pattern WC may partially cut the first and second mold structures MS1 and MS2.

The string isolation structure SC may extend in the first direction D1 to cut the string selection line. For example, the string isolation structure SC formed in the cell block BLK may cut the string selection line. The divided string selection lines may independently control each region.

The string isolation structure SC may include an insulating material, for example, silicon oxide, silicon nitride, and/or silicon oxynitride, but embodiments are not necessarily limited thereto.

The bit line BL may be formed on the first and second mold structures MS1 and MS2. The bit line BL may extend in the second direction D2 and may intersect the block isolation pattern WC. In addition, the bit line BL may extend in the second direction D2 and may be connected to the plurality of channel structures CH arranged along the second direction D2. For example, a bit line contact 174 connected to an upper portion of each of the channel structures CH may be formed in a second interlayer insulating film 194. The bit line BL may be electrically connected to the channel structures CH through the bit line contact 174

The word line contact 172 may be connected to each of the first and second gate electrodes 120 and 125. For example, the word line contact 172 may extend in the third direction D3 within the first and second interlayer insulating films 192 and 194 and be connected to the first and second gate electrodes 120 and 125, respectively. In embodiments, the word line contact 172 may have a bent portion between the first mold structure MS1 and the second mold structure MS2.

The source contact 176 may be connected to the source structure 102 and 104. For example, the source contact 176 may extend in the third direction D3 within the first and second interlayer insulating films 192 and 194 and be connected to the cell substrate 100. In embodiments, the source contact 176 may have a bent portion between the first mold structure MS1 and the second mold structure MS2.

In embodiments, the first and second mold structures MS1 and MS2 of the through region THR may include a plurality of first and second mold sacrificial films 112 and 117 and a plurality of first and second mold insulating layers 110 and 115 alternately stacked on each other on the cell substrate 100 and/or the insulating substrate 101. Each of the first and second mold sacrificial films 112 and 117 and each of the first and second mold insulating layers 110 and 115 may have a layered structure extending parallel to the upper surface of the cell substrate 100. The first and second mold sacrificial films 112 and 117 may be spaced apart from each other by the first and second mold insulating layers 110 and 115 and may be sequentially stacked on each other on the cell substrate 100.

In embodiments, the first mold structure MS1 of the through region THR may include a plurality of first mold sacrificial films 112 and the plurality of first mold insulating layers 110 alternately stacked on each other on the cell substrate 100, and the second mold structure MS2 of the through region THR may include a plurality of second mold sacrificial films 117 and the plurality of second mold insulating layers 115 alternately stacked on each other on the first mold structure MS1.

For example, the mold sacrificial film 112 and 117 may include an electrically insulating material, for example, silicon oxide, silicon nitride, and/or silicon oxynitride, but is not necessarily limited thereto. In embodiments, the first and second mold sacrificial films 112 and 117 may include a material having etch selectivity with respect to the first and second mold insulating layers 110 and 115. For example, the first and second mold insulating layers 110 and 115 may include silicon oxide, and the first and second mold sacrificial films 112 and 117 may include silicon nitride.

The first and second interlayer insulating films 192 and 194 may be formed on the cell substrate 100 and cover the first and second mold structures MS1 and MS2. In embodiments, the first and second interlayer insulating films 192 and 194 may include a first interlayer insulating film 192 and the second interlayer insulating film 194 that are sequentially stacked on each other on the cell substrate 100. The first interlayer insulating film 192 may cover the first mold structure MS1, and the second interlayer insulating film 194 may cover the second mold structure MS2. For example, the first and second interlayer insulating films 192 and 194 may include silicon oxide, silicon oxynitride, and/or a low-k material having a dielectric constant that is lower than that of silicon oxide, but is not necessarily limited thereto.

The through via 182 may be disposed in the through region THR. For example, the through via 182 may extend in the third direction D3 in the first and second mold structures MS1 and MS2 of the through region THR. In embodiments, the through via 182 may have a bent portion between the first mold structure MS1 and the second mold structure MS2. Although the through via 182 extending through the first and second mold structures MS1 and MS2 is illustrated, this is merely an example. As an example, the through via 182 may be disposed outside of the first and second mold structures MS1 and MS2 and might not penetrate through the mold structures MS1 and MS2.

The word line contact 172, the source contact 176, and the through via 182 may be connected to the first wiring structure 180 on the first and second interlayer insulating films 192 and 194, respectively. For example, a wiring insulating film 196 may be formed on the second interlayer insulating film 194. The first wiring structure 180 may be formed in the wiring insulating film 196. The word line contact 172, the source contact 176, and the through via 182 may each be connected to the first wiring structure 180 by a contact via 184. The first wiring structure 180 may be connected to the bit line BL.

In embodiments, the support structure 178 may be formed in the first and second mold structures MS1 and MS2 of the extended region EXT. The support structure 178 may be formed in a shape similar to that of the channel structure CH to reduce stress applied to the first and second mold structures MS1 and MS2 in the extended region EXT.

The peripheral circuit region PERI may include a peripheral circuit substrate 300, a peripheral circuit element 360, and a peripheral circuit wiring structure 380.

The peripheral circuit substrate 300 may be disposed under the cell substrate 100. For example, an upper surface of the peripheral circuit substrate 300 may face the second surface 100_B of the cell substrate 100. For example, the peripheral circuit substrate 300 may include a semiconductor substrate such as a silicon substrate, a germanium substrate, or a silicon-germanium substrate. Alternatively, the peripheral circuit substrate 300 may include a silicon-on-insulator (SOI) substrate or a germanium-on-insulator (GOI) substrate, etc.

The peripheral circuit element 360 may be formed on the peripheral circuit substrate 300. The peripheral circuit element 360 may configure a peripheral circuit that controls the operation of the semiconductor memory device 1100. For example, the peripheral circuit element 360 may include a logic circuit 1130, a page buffer 1120, a decoder circuit 1110, etc. of FIG. 13. In the following description, the surface of the peripheral circuit substrate 300 on which the peripheral circuit element 360 is disposed may be referred to as a front side of the peripheral circuit substrate 300. Conversely, the surface of the peripheral circuit substrate 300 opposite to the front side of the peripheral circuit substrate 300 may be referred to as a back side of the peripheral circuit substrate 300.

For example, the peripheral circuit element 360 may include a transistor, but embodiments are not necessarily limited thereto. For example, the peripheral circuit element 360 may include not only various active elements such as transistors, etc., but also various passive elements such as capacitors, resistors, inductors, etc.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed in the peripheral wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and embodiments are not necessarily limited thereto.

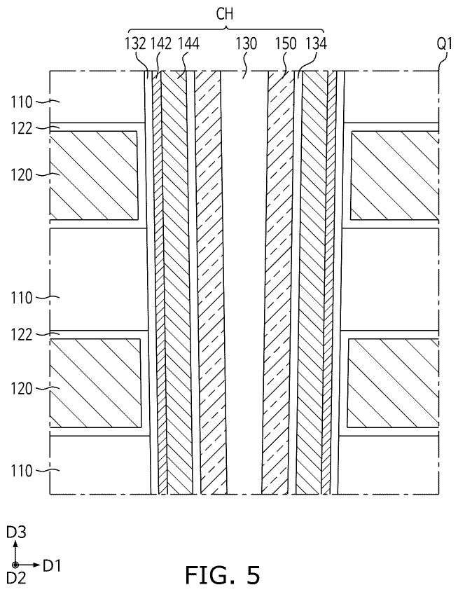

FIG. 5 is a diagram illustrating a semiconductor memory device 1100 according to embodiments. For reference, FIG. 5 may correspond to an enlarged view of the region Q1 of FIG. 2. For convenience of explanation, different configurations from those described with reference to FIGS. 1 to 4 will be mainly described and to the extent that an element is not described in detail with respect to this figure, it may be understood that the element is at least similar to a corresponding element that has been described elsewhere within the present disclosure.

Referring to FIG. 5, in the semiconductor memory device 1100, according to embodiments, the channel structure CH may include the semiconductor pattern 150, the dielectric layer 142, the ferroelectric layer 144, the first interface layer 134, a second interface layer 132, and the filling insulating layer 130.

The second interface layer 132 may be disposed between the plurality of first gate electrodes 120 and the dielectric layer 142 and between the plurality of first mold insulating layers 110 and the dielectric layer 142. The second interface layer 132 may extend in the third direction D3 along the dielectric layer 142. The second interface layer 132 may cover the dielectric layer 142. The first gate electrodes 120 may be spaced apart from the dielectric layer 142 by the second interface layer 132.

For example, the second interface layer 132 may include a silicon oxide or a high-k material (e.g., aluminum oxide (Al₂O₃), hafnium oxide (HfO₂)) having a higher dielectric constant than that of the silicon oxide.

In embodiments, the barrier layer 122 may be disposed on the first gate electrodes 120. The barrier layer 122 may surround the first gate electrodes 120. The second interface layer 132 may be in contact with the barrier layer 122 and the first mold insulating layer 110.

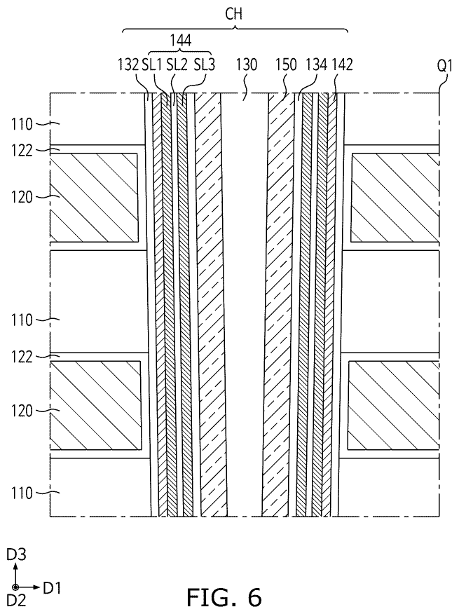

FIG. 6 is a diagram illustrating a semiconductor memory device 1100 according to embodiments. For reference, FIG. 6 may correspond to an enlarged view of the region Q1 of FIG. 2. For convenience of explanation, different configurations from those described with reference to FIGS. 1 to 5 will be mainly described and to the extent that an element is not described in detail with respect to this figure, it may be understood that the element is at least similar to a corresponding element that has been described elsewhere within the present disclosure.

Referring to FIG. 6, in the semiconductor memory device 1100 according to embodiments, the ferroelectric layer 144 may include a first sub-layer SL1, a second sub-layer SL2, and a third sub-layer SL3.

The first sub-layer SL1 may be disposed on the dielectric layer 142. The second sub-layer SL2 may be disposed on, or adjacent to, the first sub-layer SL1. The third sub-layer SL3 may be disposed on the second sub-layer SL2. For example, the first sub-layer SL1, the second sub-layer SL2, and the third sub-layer SL3 may be sequentially disposed on, or adjacent to, the dielectric layer 142.

The ferroelectric layer 144 may be a ferroelectric having a laminated structure. For example, a plurality of layers (e.g., the first to third sub-layers SL1, SL2, and SL3) stacked on the ferroelectric layer 144 may have ferroelectric properties.

In embodiments, the first sub-layer SL1 may include a ferroelectric material. The second sub-layer SL2 may include a dielectric material. The third sub-layer SL3 may include a ferroelectric material. However, embodiments are not necessarily limited thereto. The materials of the first to third sub-layers SL1, SL2, and SL3 may include various materials that impart ferroelectric properties to the ferroelectric layer 144. In addition, although it is illustrated that the ferroelectric layer 144 includes three layers (e.g., the first to third sub-layers SL1, SL2, and SL3), the ferroelectric layer 144 may include four or more layers.

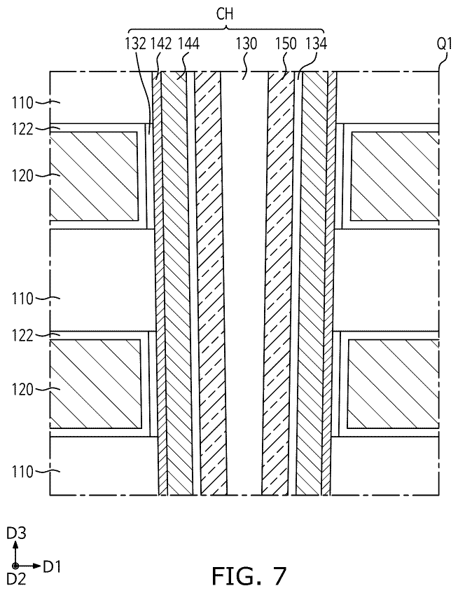

FIG. 7 is a diagram illustrating a semiconductor memory device 1100 according to embodiments. For reference, FIG. 7 may correspond to an enlarged view of the region Q1 of FIG. 2. For convenience of explanation, different configurations from those described with reference to FIGS. 1 to 5 will be mainly described and to the extent that an element is not described in detail with respect to this figure, it may be understood that the element is at least similar to a corresponding element that has been described elsewhere within the present disclosure.

Referring to FIG. 7, in the semiconductor memory device according to embodiments, the channel structure CH may include the semiconductor pattern 150, the dielectric layer 142, the ferroelectric layer 144, the first interface layer 134, the second interface layer 132, and the filling insulating layer 130.

The second interface layer 132 may be disposed on, or adjacent to, the dielectric layer 142. For example, the second interface layer 132 may contact a portion of the dielectric layer 142. The second interface layer 132 may be disposed between the plurality of first gate electrodes 120 and the dielectric layer 142. The first gate electrodes 120 may be spaced apart from the dielectric layer 142 by the second interface layer 132. The second interface layer 132 may be disposed on, or adjacent to, the dielectric layer 142 and separated at intervals in the third direction D3. For example, the second interface layer 132 might not be disposed between the plurality of first mold insulating layers 110 and the dielectric layer 142. For example, the second interface layer 132 may overlap the plurality of first gate electrodes 120 in the first direction D1, and might not overlap the plurality of first mold insulating layers 110 in the first direction D1.

For example, the second interface layer 132 may include a silicon oxide or a high-k material (e.g., aluminum oxide (Al₂O₃), hafnium oxide (HfO₂)) having a higher dielectric constant than that of the silicon oxide.

In embodiments, the barrier layer 122 may be disposed on the first gate electrodes 120. The barrier layer 122 may surround the first gate electrodes 120. The second interface layer 132 may be in contact with the barrier layer 122. The second interface layer 132 may be disposed adjacent to a corresponding barrier layer 122.

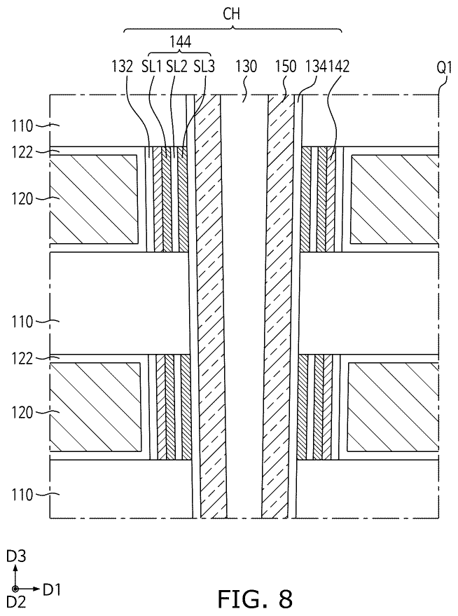

FIG. 8 is a diagram illustrating a semiconductor memory device 1100 according to embodiments. For reference, FIG. 8 may correspond to an enlarged view of the region Q1 of FIG. 2. For convenience of description, different configurations from those described above with reference to FIGS. 1 to 5 and 7 will be mainly described and to the extent that an element is not described in detail with respect to this figure, it may be understood that the element is at least similar to a corresponding element that has been described elsewhere within the present disclosure.

Referring to FIG. 8, in the semiconductor memory device 1100, according to embodiments, each of the dielectric layer 142 and the ferroelectric layer 144 may be disposed between the plurality of first gate electrodes 120 and the semiconductor pattern 150, and might not be disposed between the plurality of first mold insulating layers 110 and the semiconductor pattern 150.

The dielectric layer 142 and the ferroelectric layer 144 may be disposed between the first mold insulating layers 110 adjacent to each other in the third direction D3. The dielectric layer 142 and the ferroelectric layer 144 may be separated at intervals in the third direction D3. A length of the dielectric layer 142 and the ferroelectric layer 144 in the third direction D3 may correspond to the second interface layer 132.

The first mold insulating layer 110 may be disposed between two of the dielectric layers 142 disposed adjacent to each other along the third direction D3. The first mold insulating layer 110 may be disposed between two of the ferroelectric layers 144 disposed adjacent to each other along the third direction D3. The dielectric layer 142 and the adjacent ferroelectric layer 144 in the third direction D3 may be electrically insulated from each other. Accordingly, the charge trapped in the ferroelectric layer 144 does not move to the adjacent ferroelectric layer 144, so that the electrical characteristics of the semiconductor memory device 1100 may be improved.

In embodiments, the ferroelectric layer 144 may include the first sub-layer SL1, the second sub-layer SL2, and the third sub-layer SL3. The description of the first to third sub-layers SL1, SL2, and SL3 may be the same as that described above with reference to FIG. 6.

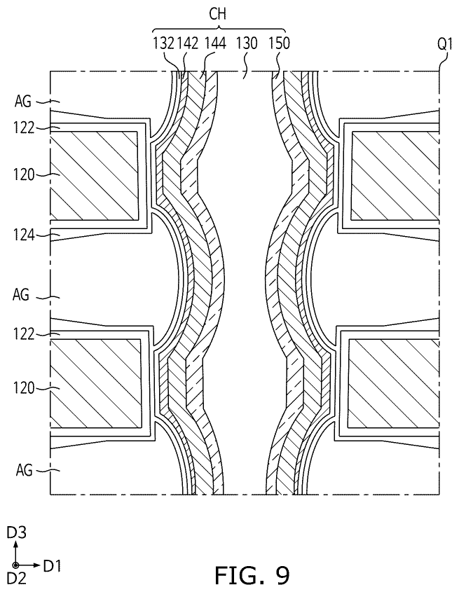

FIG. 9 is a diagram illustrating a semiconductor memory device 1100 according to embodiments. For reference, FIG. 9 may correspond to an enlarged view of the region Q1 of FIG. 2. For convenience of explanation, different configurations from those described with reference to FIGS. 1 to 5 will be mainly described and to the extent that an element is not described in detail with respect to this figure, it may be understood that the element is at least similar to a corresponding element that has been described elsewhere within the present disclosure.

Referring to FIGS. 2 and 9, in the semiconductor memory device 1100 according to embodiments, the first mold structure MS1 may further include a sealing layer 124 and an air gap AG.

The air gap AG may be disposed on the plurality of first gate electrodes 120. The air gap AG may be disposed between the gate electrodes 120 adjacent to each other in the third direction D3. The air gap AG may be disposed in the sealing layer 124. The air gap AG may include a protrusion protruding toward the channel structure CH. The protrusion of the air gap AG may protrude adjacent to the channel structure CH further than an end portion of the first gate electrodes 120. The protrusion of the air gap AG may have a convex shape adjacent to the channel structure CH. The inside of the air gap AG may be empty.

The sealing layer 124 may surround the air gap AG. The sealing layer 124 may be disposed on the barrier layer 122 and the protrusion of the air gap AG. A portion of the sealing layer 124 may correspond to the shape of the protrusion of the air gap AG, and may have a convex shape toward the channel structure CH. The sealing layer 124 may surround the channel structure CH.

In embodiments, the channel structure CH may be disposed along the profile of the sealing layer 124. For example, the second interface layer 132 may extend along the profile of the sealing layer 124. A portion of the second interface layer 132 may have a convex curve (or a curved surface concave inward towards the channel structure CH) corresponding to the protrusion of the air gap AG.

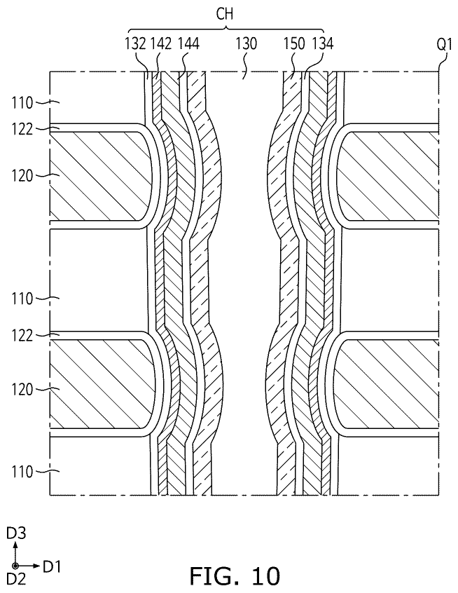

FIG. 10 is a diagram illustrating a semiconductor memory device 1100 according to embodiments. For reference, FIG. 10 may correspond to an enlarged view of the region Q1 of FIG. 2. For convenience of explanation, different configurations from those described with reference to FIGS. 1 to 5 will be mainly described and to the extent that an element is not described in detail with respect to this figure, it may be understood that the element is at least similar to a corresponding element that has been described elsewhere within the present disclosure.

Referring to FIG. 10, in the semiconductor memory device 1100, according to embodiments, the first gate electrodes 120 may include a rounding portion protruding towards the channel structure CH. The rounding portion of the first gate electrodes 120 may have a convex shape.

The channel structure CH may be disposed on, or adjacent to, the rounding portion of the first gate electrodes 120. The channel structure CH may have a concave shape corresponding to the rounding portion of the first gate electrodes 120. For example, a sidewall of the sidewalls of the channel structure CH, which is disposed on, or adjacent to, the first gate electrodes 120, may have a concave curved surface.

The channel structure CH may include a plurality of curved surfaces corresponding to rounding portions of the plurality of first gate electrodes 120. For example, the semiconductor pattern 150 may include a plurality of curved portions corresponding to the protruding rounding portions of the plurality of first gate electrodes 120. Compared with the length of the semiconductor pattern 150 of FIG. 4, the length of the semiconductor pattern 150 including a plurality of curved portions may be longer. This length may refer to a length in the third direction D3.

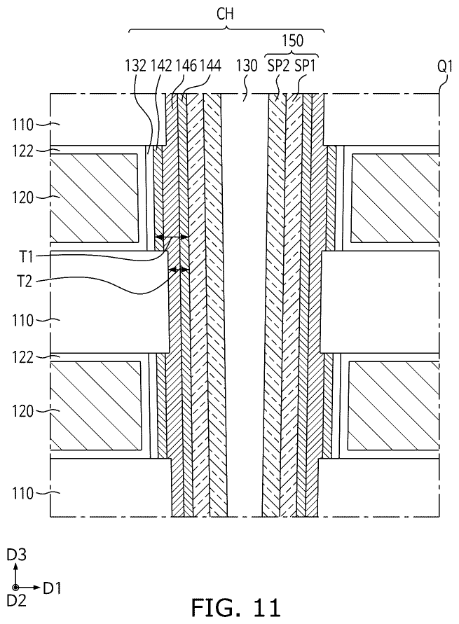

FIG. 11 is a diagram illustrating a semiconductor memory device 1100 according to embodiments. For reference, FIG. 11 may correspond to an enlarged view of the region Q1 of FIG. 2. For convenience of explanation, different configurations from those described with reference to FIGS. 1 to 7 will be mainly described and to the extent that an element is not described in detail with respect to this figure, it may be understood that the element is at least similar to a corresponding element that has been described elsewhere within the present disclosure.

Referring to FIG. 11, in the semiconductor memory device 1100, according to embodiments, the channel structure CH may include the semiconductor pattern 150, the dielectric layer 142, the ferroelectric layer 144, an anti-ferroelectric layer 146, the second interface layer 132, and the filling insulating layer 130.

The dielectric layer 142 may be disposed on the second interface layer 132. The dielectric layer 142 may extend along the second interface layer 132. The length of the dielectric layer 142 in the third direction D3 may correspond to the length of the second interface layer 132 in the third direction D3. In one example, the dielectric layer 142 may be a ferroelectric layer.

The anti-ferroelectric layer 146 may be disposed between the dielectric layer 142 and the ferroelectric layer 144, and between the first mold insulating layer 110 and the ferroelectric layer 144. The anti-ferroelectric layer 146 may include an antiferroelectric material. In embodiments, the thickness of the anti-ferroelectric layer 146 might not be constant. For example, a thickness of a portion of the anti-ferroelectric layer 146, which overlaps the first gate electrodes 120 in the first direction D1 may be greater than a thickness of a portion that overlaps the first mold insulating layer 110. However, embodiments are not necessarily limited thereto. Unlike the illustration, the thickness of the anti-ferroelectric layer 146 may be constant.

The ferroelectric layer 144 may be disposed on, or adjacent to, the anti-ferroelectric layer 146. The ferroelectric layer 144 may extend along the anti-ferroelectric layer 146 in the third direction D3.

A distance from the outer surface of the semiconductor pattern 150 to an outer surface of the dielectric layer 142 may be a first thickness T1. For example, the first thickness T1 may include the thickness of the dielectric layer 142, anti-ferroelectric layer 146, and the ferroelectric layer 144. A distance from the outer surface of the semiconductor pattern 150 to an outer surface of the anti-ferroelectric layer 146 may be a second thickness T2. For example, the second thickness T2 may include the thickness of the ferroelectric layer 146, and the ferroelectric layer 144. The outer surface of the dielectric layer 142 may be a boundary surface between the dielectric layer 142 and the second interface layer 132, and the outer surface of the anti-ferroelectric layer 146 may be a boundary surface between the anti-ferroelectric layer 146 and the first mold insulating layer 110. The first thickness T1 may be greater than the second thickness T2. In embodiments, the first thickness T1 may be within a range of 0.1 nm to 20 nm, inclusive, and the second thickness T2 may be within a range of 0.1 nm to 15 nm, inclusive.

In embodiments, the semiconductor pattern 150 may include a first sub-pattern SP1 and a second sub-pattern SP2. The first sub-pattern SP1 may be disposed between the second sub-pattern SP2 and the ferroelectric layer 144. The second sub-pattern SP2 may be disposed between the first sub-pattern SP1 and the filling insulating layer 130. The first sub-pattern SP1 may include an In—Ga—Zn-based oxide (e.g., an In—Ga—Zn-based oxide (IGZO)), and the second sub-pattern SP2 may include single crystalline or polycrystalline silicon doped with a P-type dopant.

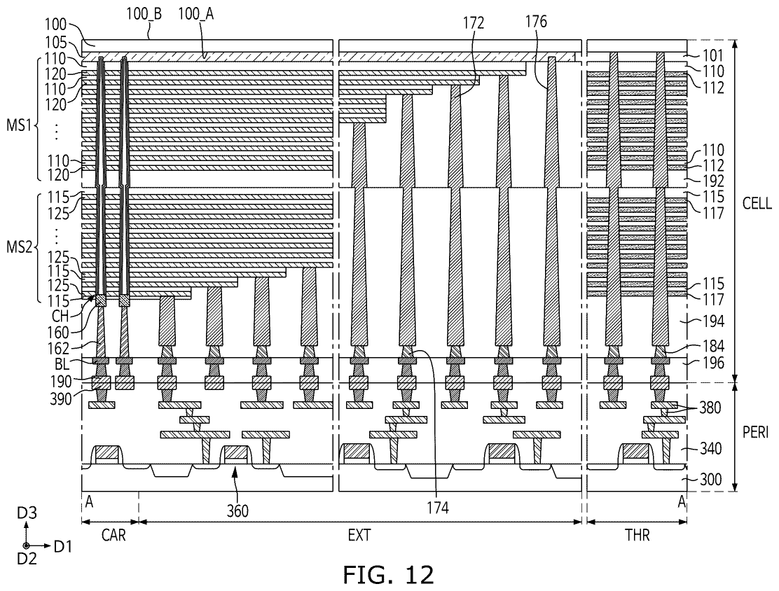

FIG. 12 is a diagram illustrating a semiconductor memory device 1100 according to embodiments.

Referring to FIG. 12, the semiconductor memory device 1100, according to embodiments, may include a common source plate 105.

The common source plate 105 may be disposed on, or below, the first surface 100_A of the cell substrate 100. The common source plate 105 may be connected to the channel structure CH. For example, the common source plate 105 may be electrically connected to the semiconductor pattern 150 of the channel structure CH. The common source plate 105 may be used as a common source line (e.g., CSL of FIG. 13) of the semiconductor memory device 1100. The first mold structure MS1 and the second mold structure MS2 may be disposed on, or below, the common source plate 105. For example, the common source plate 105 may include polycrystalline silicon or metal doped with an impurity, but embodiments are not necessarily limited thereto.

The semiconductor memory device 1100, according to embodiments, may have a chip-to-chip (C2C) structure. The C2C structure refers to the manufacturing of an upper chip including the memory cell area CELL on a first wafer (e.g., the cell substrate 100), manufacturing a lower chip including the peripheral circuit region PERI on a second wafer (e.g., the peripheral circuit substrate 300) which is different from the first wafer, and connecting the upper and lower chips to each other by a bonding method.

In embodiments, the bonding method may be a method of electrically connecting a first bonding metal 190, formed on the lowermost metal layer of the upper chip, and a second bonding metal 390, formed on, or below, the uppermost metal layer of the lower chip, to each other. For example, if the first bonding metal 190 and the second bonding metal 390 are formed of copper (Cu), the bonding method may be a Cu—Cu bonding method. However, this is only an example, and the first bonding metal 190 and the second bonding metal 390 may be formed of various other metals such as aluminum (Al) or tungsten (W).

As the first bonding metal 190 and the second bonding metal 390 are bonded to each other, the first wiring structure 180 may be connected to a second wiring structure. Accordingly, the bit line BL and each of the gate electrodes 120 and 125 may be electrically connected to the peripheral circuit element 360.

FIG. 13 is a block diagram illustrating an example of an electronic system according to embodiments.

Referring to FIG. 13, an electronic system 1000 may include a semiconductor memory device 1100 described above with reference to FIGS. 1 to 12, and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device including one or a plurality of semiconductor memory devices 1100.

For example, the semiconductor memory device 1100 may be the NAND flash memory device described above with reference to FIGS. 1 to 12. The semiconductor memory device 1100 may include a first structure 1100F and a second structure 1100S that is disposed on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR that is disposed between the bit line BL and the common source line CSL.

In the second structure 1100S, each of the memory cell strings CSTR may include lower transistors LT1 and LT2, which are disposed adjacent to the common source line CSL and upper transistors UT1 and UT2, which are disposed adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In example embodiments, the upper transistors UT1 and UT2 may include a string select transistor, and the lower transistors LT1 and LT2 may include a ground select transistor. The first and second gate lower lines LL1 and LL2 each may be gate electrodes of the lower transistors LT1 and LT2. The word lines WL may be gate electrodes of the memory cell transistors MCT, and the first and second gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from the first structure 1100F to the second structure 1100S. The bit lines BL may be electrically connected to the page buffer 1120 through second connection wires 1125 extending from the first structure 1100F to the second structure 1100S.

In the first structure 1100F, the decoder circuit 1110 and the page buffer 1120 may perform a control operation on at least one memory cell transistor among the plurality of memory cell transistors MCT. The decoder circuit 1110 and the page buffer 1120 may be controlled by the logic circuit 1130. The semiconductor memory device 1100 may communicate with the controller 1200 through the input and output pad 1101 which is electrically connected to the logic circuit 1130. The input and output pad 1101 may be electrically connected to the logic circuit 1130 through an input and output connection wiring 1135 extending from the first structure 1100F to the second structure 1100S.

The controller 1200 may include a processor 1210, a NAND controller 1220, and a host interface 1230. According to embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a function of facilitating communication between the electronic system 1000 and an external host. Upon receiving a control command from the external host through the host interface 1230, the processor 1210 may control the semiconductor memory device 1100 in response to the control command.

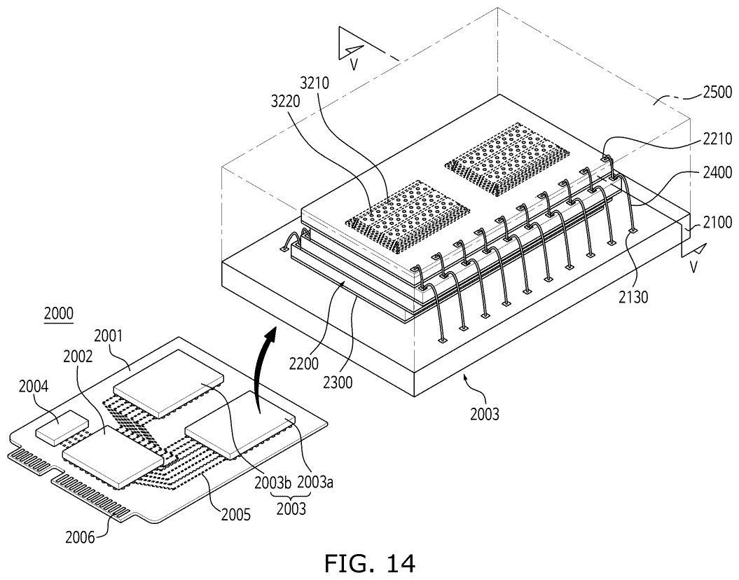

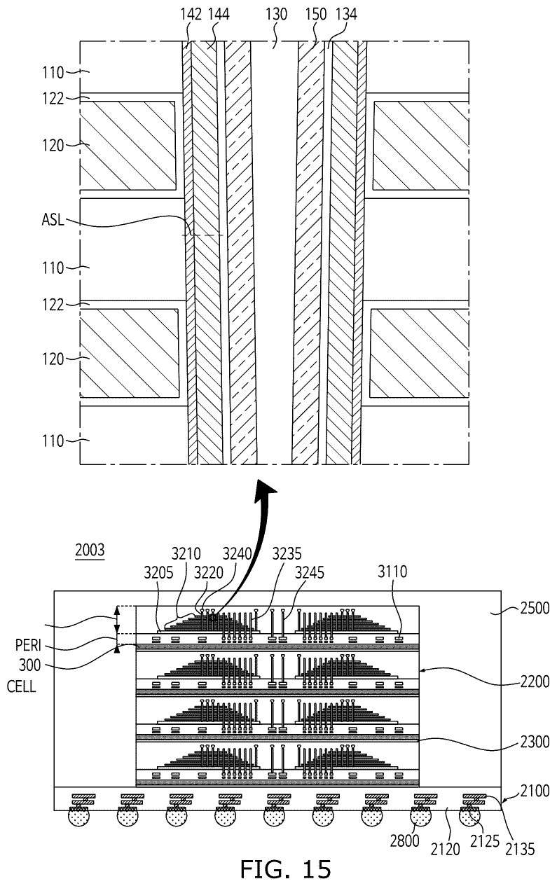

FIG. 14 is an example perspective view illustrating an electronic system 2000 including a semiconductor memory device 1100 according to embodiments. FIG. 15 is a schematic cross-sectional view taken along line V-V of FIG. 14.

Referring to FIG. 14, the electronic system 2000 may include a main substrate 2001, a controller 2002 mounted on the main substrate 2001, one or more semiconductor packages 2003, and a dynamic random-access memory (DRAM 2004). The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In embodiments, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In embodiments, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may increase the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a type of cache memory, and may also provide a space for temporarily storing data in a control operation for the semiconductor package 2003. If the electronic system 2000 includes the DRAM 2004, in addition to the NAND controller 1220 for controlling the semiconductor package 2003, the main controller 2002 may further include a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 disposed on the package substrate 2100.

The package substrate 2100 may be a printed circuit substrate including package upper pads 2130. Each of the semiconductor chips 2200 may include an input and output pad 2210. The input and output pad 2210 may correspond to the input and output pad 1101 of FIG. 13. Each of the semiconductor chips 2200 may include metal lines and channel structures 3220. Each of the semiconductor chips 2200 may include the semiconductor memory device 1100 described above with reference to FIGS. 1 to 12.

In embodiments, the connection structure 2400 may be a bonding wire electrically connecting the input and output pad 2210 to the package upper pads 2130. Accordingly, in each of the first and second semiconductor packages 2003a and 2003b, the semiconductor chips 2200 may be electrically connected to each other with the bonding wire method, and may be electrically connected to the package upper pads 2130 of the package substrate 2100. In embodiments, in each of the first and second semiconductor packages 2003a and 2003b, the semiconductor chips 2200 may be electrically connected to each other through a connection structure including through-electrodes such as through silicon via (TSV) instead of the bonding wire type connection structure 2400.

In embodiments, the main controller 2002 and the semiconductor chips 2200 may be included in one package. In embodiments, the main controller 2002 and the semiconductor chips 2200 may be mounted on a separate interposer substrate, which is different from the main substrate 2001, and the main controller 2002 and the semiconductor chips 2200 may be connected to each other through wiring formed on the interposer substrate.

In embodiments, the package substrate 2100 may be a printed circuit substrate. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125, which is disposed within the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 14.

In an electronic system according to embodiments, each of the semiconductor chips 2200 may include the semiconductor memory device 1100 described above with reference to FIGS. 1 to 12. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 described above with reference to FIGS. 1 to 12 and a peripheral wiring 3110. In addition, for example, the cell structure CELL may include a common source line 3205, a gate stack structure 3210 on the common source line 3205, a channel structure 3220 and an isolation structure penetrating through the gate stack structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may penetrate through the gate stack structure 3210 and may be further disposed outside of the gate stack structure 3210. Each of the semiconductor chips 2200 may further include an input and output connection wiring electrically connected to the peripheral wiring 3110 of the peripheral circuit structure PERI and extending into a second structure 3200, and the input and output pad 2210 electrically connected to the input and output connection wiring.

Although certain embodiments of the present disclosure have been described with reference to the accompanying drawings, those of ordinary skill in the art to which the present disclosure pertains will understand that the present disclosure may be implemented in other forms without changing its technical idea or essential features. Therefore, it should be understood that the embodiments described above are illustrative and not necessarily limiting.

1. A semiconductor memory device, comprising:
a substrate;
a mold structure disposed on the substrate, the mold structure including a plurality of mold insulating layers and a plurality of gate electrodes alternately stacked in a first direction; and
a channel structure penetrating through the mold structure and extending in the first direction,
wherein the channel structure includes:
a semiconductor pattern;
a dielectric layer; and
a ferroelectric layer,
wherein the dielectric layer and the ferroelectric layer are each disposed between the plurality of gate electrodes and the semiconductor pattern,
wherein a concentration of a specific element in the dielectric layer is greater than a concentration of the specific element in the ferroelectric layer, and
wherein the specific element includes carbon and/or nitrogen.

2. The semiconductor memory device according to claim 1, wherein a thickness of the dielectric layer in a second direction intersecting the first direction is less than a thickness of the ferroelectric layer in the second direction.

3. The semiconductor memory device according to claim 1, wherein the concentration of the specific element in the dielectric layer is between 2 and 20 atomic percent, inclusive.

4. The semiconductor memory device according to claim 1, wherein the dielectric layer is disposed between the plurality of gate electrodes and the ferroelectric layer.

5. The semiconductor memory device according to claim 1, wherein a thickness of the dielectric layer is between 0.1 nm and 3 nm, inclusive.

6. The semiconductor memory device according to claim 1, wherein the channel structure further includes a first interface layer disposed between the semiconductor pattern and the ferroelectric layer.

7. The semiconductor memory device according to claim 1, wherein the channel structure further includes a second interface layer disposed between the dielectric layer and the plurality of gate electrodes.

8. The semiconductor memory device according to claim 7, wherein the second interface layer extends along an outer surface of the dielectric layer.

9. The semiconductor memory device according to claim 7, wherein the second interface layer is not present between the plurality of mold insulating layers and the dielectric layer.

10. The semiconductor memory device according to claim 1,
wherein the ferroelectric layer includes a first sub-layer, a second sub-layer, and a third sub-layer sequentially disposed on the dielectric layer,
wherein the first sub-layer and the third sub-layer each include a ferroelectric material, and
wherein the second sub-layer includes a dielectric material.

11. The semiconductor memory device according to claim 1, further comprising an air gap disposed between two gate electrodes, of the plurality of gate electrodes, that are adjacent to each other in the first direction.

12. The semiconductor memory device according to claim 1,
wherein each of the plurality of gate electrodes further includes a rounding portion protruding toward the channel structure, and
wherein the semiconductor pattern includes a plurality of curved portions corresponding to the protruding rounding portions of the plurality of gate electrodes.

13. The semiconductor memory device according to claim 1, wherein the channel structure further includes an anti-ferroelectric layer disposed between the dielectric layer and the ferroelectric layer.

14. The semiconductor memory device according to claim 1,
wherein the semiconductor pattern includes a first sub-pattern and a second sub-pattern,
wherein the first sub-pattern includes an indium gallium zinc oxide (IGZO), and
wherein the second sub-pattern includes a P-type dopant.

15. The semiconductor memory device according to claim 1, wherein the dielectric layer includes HfO₂, ZrO₂, SiO₂, SiN, TiO₂, Al₂O₃ and/or VO₂.

16. The semiconductor memory device according to claim 1, wherein the dielectric layer includes a two-dimensional material.

17. A semiconductor memory device, comprising:
a peripheral circuit structure; and
a cell structure stacked on the peripheral circuit structure,
wherein the cell structure includes:
a substrate;
a mold structure disposed on the substrate; and
a channel structure penetrating through the mold structure and extending in a first direction,
wherein the mold structure includes a plurality of mold insulating layers and a plurality of gate electrodes alternately stacked on each other in the first direction,
wherein the channel structure includes:
a semiconductor pattern; and
a dielectric layer and a ferroelectric layer disposed between the plurality of gate electrodes and the semiconductor pattern,
wherein a concentration of a specific element in the dielectric layer is greater than a concentration of the specific element in the ferroelectric layer, and
wherein the specific element includes carbon and/or nitrogen.

18. The semiconductor memory device according to claim 17, wherein the cell structure further includes:
a channel pad connected to the channel structure;
a bit line connected to the channel pad; and
a cell wiring structure bonded between the bit line and the peripheral circuit structure.

19. The semiconductor memory device according to claim 17, wherein the dielectric layer is disposed between the plurality of gate electrodes and the ferroelectric layer.

20. An electronic system, comprising:
a main substrate;
a semiconductor memory device disposed on the main substrate, the semiconductor memory device including a peripheral circuit structure, and a cell structure stacked on the peripheral circuit structure; and
a controller disposed on the main substrate, the controller being electrically connected to the semiconductor memory device,
wherein the cell structure includes:
a substrate;
a mold structure disposed on the substrate; and
a channel structure penetrating through the mold structure and extending in a first direction,
wherein the mold structure includes a plurality of mold insulating layers and a plurality of gate electrodes alternately stacked in the first direction,
wherein the channel structure includes:
a semiconductor pattern;
a dielectric layer; and
a ferroelectric layer,
wherein the dielectric layer and the ferroelectric layer are each disposed between the plurality of gate electrodes and the semiconductor pattern,
wherein a concentration of a specific element in the dielectric layer is greater than a concentration of the specific element in the ferroelectric layer, and
wherein the specific element includes carbon and/or nitrogen.
